(19) United States
(12) Patent Application Publication
(10) Pub. No.: US 2008/0305435 A1
(43) Pub. Date: Dec. 11, 2008

(54) METHOD OF MAKING LITHOGRAPHIC PRINTING PLATE SUBSTRATE AND IMAGEABLE ELEMENTS

(76) Inventor: Yasushi Miyamoto, Tatebayashi (JP)

Correspondence Address: Andrew J. Anderson;Patent Legal Staff, Eastman Kodak Company, 343 State Street, Rochester, NY, 14650-2201, US

(21) Appl. No.: 11/758,181

(22) Filed: Jun. 5, 2007

(51) Int. Cl. G03F 7/00; G03C 5/00

(52) U.S. Cl. 430/302; 430/331

(57) ABSTRACT

Aluminum-containing substrates having an anodic oxide layer are coated with a interlayer by carefully controlling the concentration of phosphonic acid groups in an interlayer polymer and aluminum (+3) concentration in a post-treatment solution. These substrates have improved hydrophilicity, lithographic printing ink repellency, and overall improved printability when used as part of lithographic printing plates.

### FIELD OF THE INVENTION

This invention relates to a method of preparing an aluminum-containing substrate and to imageable elements, such as lithographic printing plate precursors, prepared from this substrate.

### BACKGROUND OF THE INVENTION

In conventional or “wet” lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. For example, the ink can be first transferred to an intermediate blanket that in turn is used to transfer the ink to the surface of the material upon which the image is to be reproduced.

Imageable elements useful to prepare lithographic printing plates typically comprise an imageable layer applied over the hydrophilic surface of a substrate. The imageable layer includes one or more radiation-sensitive components that can be dispersed in a suitable binder. Alternatively, the radiation-sensitive component can also be the binder material. Following imaging, either the imaged regions or the non-imaged regions of the imageable layer are removed by a suitable developer, revealing the underlying hydrophilic surface of the substrate. If the imaged regions are removed, the element is considered as positive-working. Conversely, if the non-imaged regions are removed, the element is considered as negative-working. In each instance, the regions of the imageable layer (that is, the image areas) that remain are ink-receptive, and the regions of the hydrophilic surface revealed by the developing process accept water and aqueous solutions, typically a fountain solution, and repel ink.

Independently of the type of imageable element, lithography has generally been carried out using a metal substrate (or “support”) such as a substrate comprising aluminum or an aluminum alloy of various metallic compositions. The surface of the metal sheet is generally roughened by surface graining in order to ensure good adhesion to a layer, usually an imageable layer, that is disposed thereon and to improve water retention in non-imaged regions during printing. Such aluminum-supported imageable elements are sometimes known in the art as precursors to planographic printing plates or lithographic printing plates.

Various aluminum support materials and methods of preparing them are described in U.S. Pat. No. 5,076,899 (Sakaki et al.) and U.S. Pat. No. 5,518,589 (Matsura et al.).

To prepare aluminum-containing substrates for lithographic elements, a continuous web of raw aluminum can be treated, for example, using the sequence of steps that is schematically illustrated in FIG. 1.

The continuous aluminum web is generally taken from unwind section 1 through degreasing section 2 to remove oils and debris from the aluminum web, alkali etching section 3, first rinsing section 4, graining section 5 (that can include mechanical or electrochemical graining, or both), second rinsing section 6, post-graining acidic- or alkali-etching section 7, third rinsing section 8, anodization section 9 using a suitable acid to provide an anodic oxide coating, fourth rinsing section 10, post-treatment section 11, final or fifth rinsing section 12, and drying section 13, before either being rewound or passed on to coating stations for application of imageable layer formulations.

In the anodization section, the aluminum web is treated to form an aluminum oxide layer on its surface so it will exhibit a high degree of mechanical abrasion resistance necessary during the printing process. This oxide layer is already hydrophilic to some degree, which is significant for having a high affinity for water and for repelling printing ink. However, the oxide layer is so reactive that is can interact with components of the imageable layer in the imageable element. The oxide layer may partially or completely cover the aluminum substrate surface.

In the post-treatment section (post-treatment section 11 in FIG. 1 described above), the oxide layer is covered with a hydrophilic protective layer (also known in the art as a “seal”, “sublayer”, or “interlayer”) to increase its hydrophilicity before one or more imageable layer formulations are applied. The hydrophilic protective layer can be applied by immersing the web in the post-treatment solution or by spraying the solution onto the web (with optional recovery tank, filter, and fluid delivery system). A suitable interlayer may also ensure that during development, the soluble regions of the imageable layer are easily removed from the substrate, leaving no residue and providing clean hydrophilic backgrounds. The hydrophilic interlayer can also protect the aluminum oxide layer against corrosion during development with highly alkaline developers and from dye penetration from the imageable layer.

A variety of organic substances have been described for this purpose. Generally, these substances are polymers having functional groups such as carboxy, sulfonic acid, phosphonic acid, mercapto, hydroxyl, or amine groups. Phosphono-substituted siloxane hydrophilic protective layers are described in WO 2006/021446 (Fiebag et al.). Vinyl copolymers are described for the same purpose in U.S. Pat. No. 7,049,048 (Hunter et al.). Alternatively, copolymers containing polyalkylene oxide side chains can be used in hydrophilic protective layers as described in WO 2006/028440 (Strehmel et al.).

Other hydrophilic protective layers are prepared from formulations including poly(vinyl phosphonic acid) (PVPA), vinyl phosphonic acid/acrylic acid (VPA/AA) copolymers, and poly(acrylic acid) (PAA) as described for example in U.S. Pat. No. 4,153,461 (Berghauser et al.) and EP 0 537 633B1 (Elsaesser et al.). U.S. Pat. No. 6,218,075 (Kimura et al.) describes the treatment of metal substrates with various compositions of poly(vinyl phosphonic acid).

U.S. Pat. No. 4,427,765 (Mohr et al.) describes the use of a water-soluble organic polymer having acidic functional groups (such as phosphorous or sulfonic acid groups) with a salt of a divalent metal cation. Various organic polymers and metal cations are described that are believed to form a complex of polymer and metal cation. U.S. Pat. No. 5,314,787 (Elsaesser et al.) describes the treatment of aluminum substrates with a hydrophilic polymer solution followed by treatment with a solution containing divalent or polyvalent metal cations.

### Problem to be Solved

The noted polymers are generally applied to the aluminum web that is being moved through a post-treatment solution containing the polymer at a fixed speed. During this manufacturing step, the polymer concentration is generally kept within a specified range by replenishing the post-treatment solution. At the same time, aluminum ions originating from the moving web increases aluminum (+3) concentration in the post-treatment solution thereby creating a “seasoned” treatment solution. During a typical manufacturing run starting with a “fresh” post-treatment solution, the amount of aluminum (+3) increases and causes a variation in the amount of polymer deposited on the moving web. This change in aluminum ion concentration results in the printing plate substrates prepared during one phase of the production run to be different from the substrates prepared during another phase of the production run. This variability in the aluminum substrate may adversely affect its hydrophilicity, printability, adhesion, or other properties.

There is a need to improve the hydrophilicity (water acceptance), ink repellency, and overall printability characteristics of the aluminum substrates in lithographic printing plates, by reducing variability in the substrate surface properties obtained during the post-treatment process.

### SUMMARY OF THE INVENTION

This invention addresses the problems noted above by providing a method of preparing an aluminum-containing substrate, the method comprising:

treating an aluminum support surface having an anodic oxide layer, with an aqueous post-treatment solution comprising a polymer derived from vinyl phosphonic acid and an Al⁺³ salt, wherein the concentration of the polymer is maintained in the post-treatment solution at a concentration of within ±50% of a target polymer concentration of from about 1.5×10⁻⁴ to about 1.5 mol phosphonic acid groups per liter, and the concentration of Al⁺³ is maintained in the post-treatment solution at a concentration of within ±50% of target Al⁺³ concentration within the range of from about 1×10⁻⁶ to about 1×10⁻¹ mol/liter, the treating step being sufficient to deposit at least 3×10⁻⁶ mole of phosphonic acid groups per m² of the support.

Thus, the present invention also provides aluminum-containing substrates provided by the noted method and imageable elements prepared from these substrates having one or more imageable layers disposed thereon.

The aluminum-containing substrates provided by the method of this invention exhibit improved substrate hydrophilicity, ink repellency, and overall improved printability properties even when reduced fountain solution is used during printing. It addition, it was noticed that aluminum substrates prepared by this invention exhibit improved ink clean-up properties so less printed sheets are needed to achieve desired clean images. Thus this invention provides thermal positive working “computer-to-plate” lithographic printing plates having improved printability and ink cleanup properties.

These advantages are achieved by carefully controlling the concentration of aluminum (+3) and vinyl phosphonic acid polymer concentrations in the post-treatment solution used to apply the polymer interlayer to the aluminum support. It is particularly useful that the aluminum (+3) concentration be controlled within a target concentration range so the concentration variability occurring in known post-treatment solutions is reduced and thereby producing more consistent aluminum surface (and polymer interlayer) properties. For example, the post-treatment solution can be monitored and the aluminum (+3) concentration controlled so that the post-treatment solution is like a “seasoned” solution even at the beginning of its use.

### BRIEF DESCRIPTION OF THE DRAWING

FIG. 1 is a schematic representation of a typical method of manufacturing an aluminum-containing substrate for lithographic printing plates, as described above in the Background of the Invention.

### DETAILED DESCRIPTION OF THE INVENTION

Definitions

Unless the context indicates otherwise, when used herein, the terms “aluminum-containing substrate”, “imageable element”, “positive-working imageable element”, and “printing plate precursor” are meant to be references to embodiments of the present invention.

The term “support” is used herein to refer to an aluminum-containing material (web, sheet, foil, or other form) that is then treated to prepare an “aluminum-containing substrate” that refers to the hydrophilic article upon which various layers are coated. Thus, “aluminum-containing substrate” refers to the article that is produced by the method of this invention.

The terms “post-treatment solution” and “aqueous post-treatment solution” refer to the aqueous solution used to coat an interlayer on the anodized substrate (for example, the moving anodized aluminum web).

In addition, unless the context indicates otherwise, the various components described herein such as the components of the various layers in the imageable elements or of the aqueous solutions used in the method of this invention, refer to one or more of those components. Thus, the use of the article “a” or “an” is not necessarily meant to refer to only a single component.

Unless otherwise indicated, percentages refer to percents by dry weight or % solids.

As used herein, the term “radiation absorbing compound” refers to compounds that are sensitive to certain wavelengths of radiation and can convert photons into heat within the layer in which they are disposed. These compounds may also be known as “photothermal conversion materials”, “sensitizers”, or “light to heat convertors”.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

Unless otherwise indicated, the term “polymer” refers to high and low molecular weight polymers including oligomers and includes homopolymers and copolymers.

The term “copolymer” refers to polymers that are derived from two or more different monomers. That is, they comprise recurring units having from about two different chemical structures.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

Uses

The treated aluminum-containing substrates prepared according to this invention can be used to prepare imageable elements of this invention that can be used in a number of ways. For example, the substrates can be used to prepare precursors to lithographic printing plates as described in more detail below. However, this is not meant to be the only use of the present invention. For example, the aluminum-containing substrates can be used for any application requiring hydrophilic aluminum-containing surfaces. Moreover, the imageable elements can also be used as thermal patterning systems and to form masking elements and printed circuit boards.

Substrate

The substrates prepared according to this invention are generally provided initially as an electrochemically grained support having aluminum as the predominant component, and including supports of pure aluminum and aluminum alloys. Thus, the electrochemically grained metal support can be composed of pure aluminum, aluminum alloys having small amounts (up to 10% by weight) of other elements such as manganese, silicon, iron, titanium, copper, magnesium, chromium, zinc, bismuth, nickel, or zirconium, or be polymeric films or papers on which a pure aluminum or aluminum alloy sheet is laminated or deposited (for example, a laminate of an aluminum sheet and a polyester film). Generally, the electrochemically grained pure aluminum or aluminum alloys are used in this invention. The supports can be in any useful form or shape including continuous webs, sheets, and coils.

The thickness of the resulting aluminum-containing substrate can be varied but should be sufficient to sustain the wear from printing and thin enough to wrap around a printing form. Generally, support sheets have a thickness of from about 100 to about 600 μm.

In general, the supports used to prepare as substrates have the desired tensile strength, elasticity, crystallinity, conductivity, and other physical properties that are conventional in the lithographic art, which properties can be achieved using known treatments such as heat treatment, cold or hot fabrication processes, or other methods conventional in the art of aluminum alloy fabrication for lithographic substrate preparation.

The substrates can be prepared as continuous webs or coiled strips to provide substrates as continuous webs that can be cut into desired sheets at a later time.

The aluminum surface of the support is generally cleaned, roughened, and anodized using suitable known procedures before the method of the phosphonic acid groups are applied according to this invention. For example, a degreasing treatment with a surfactant, an organic solvent, or an alkaline water solution is typically used to remove oil and grease from the surface of the support. Then, the surface may be roughened (or grained) by well known techniques, such as mechanical roughening, electrochemical roughening, or a combination thereof (multi-graining). Electrochemically graining can be carried out in a suitable manner as described for example in U.S. Pat. No. 7,049,048 (noted above) that is incorporated herein for the graining procedures.

In some embodiments, the surface of the aluminum-containing support can be electrochemically grained using the procedure and chemistry described in copending and commonly assigned U.S. Ser. No. 11/478,266 (filed Jun. 29, 2006 by Hunter, Hunter, Motoc, Doescher, Sroka, Huang, and Blum) that is also incorporated herein. In these procedures, the roughened aluminum-containing support is subjected to alternating current preferably in an electrolytic solution containing a suitable strong acid such as hydrochloric, nitric acid, or mixtures thereof. The acidic concentration of the electrolytic solution is generally from about 0.4% and typically from about 0.7% to about 2% for hydrochloric acid, or from about 0.2% and typically from about 0.4% to about 2.5% for nitric acid. Optional additives can be present in the electrolytic solution as corrosion inhibitors or stabilizers including but not limited to, metal nitrates and chlorides (such as aluminum nitrate and aluminum chloride), monoamines, diamines, aldehydes, phosphoric acid, chromic acid, boric acid, lactic acid, acetic acid, and oxalic acid.

This electrochemical graining is most commonly carried out at a temperature of from about 18 to about 50° C. and typically from about 20° C. to about 40° C. The temperature can be optimized by routine experimentation for a given acid concentration and level of dissolved aluminum to best control pit depth.

The alternating current used in the graining process can have any desired wave form that alternates between positive and negative voltages including but not limited to, a square wave, trapezoidal wave, or sine wave. Ordinary single-phase or three-phase current can be used. Graining is carried out at a current density of from about 50 to about 200 A/dm², and typically from about 50 to about 80 A/dm².

The charge density is generally less than or equal to 850 coulombs/dm² and typically from about 450 and up 750 coulombs/dm². The appropriate current density can be chosen based on the specific acid and its concentration that are used. For example, if the hydrochloric acid concentration is from about 0.7 to about 1.1%, the charge density should be a maximum of 600 coulombs/dm² (typically from about 500 to about 550 C/dm²). If the acid concentration is increased from about 1.1 to about 1.4%, the charge density should be a maximum of 750 C/dm² (typically from about 550 to about 650 C/dm²).

Electrochemical graining can be carried out at the same charge density throughout the process or it the charge density can be changed in a stepwise fashion whereby each graining step is carried out at a different current density than the previous or succeeding graining step. For example, a stepwise graining process can be accomplished by successively increasing (“ramping up”) or decreasing (“ramping down”) current densities in succeeding graining steps.

The particular graining current density and the manner in which it is used are controlled to provide a surface centerline average roughness (Ra) of less than 0.60 μm and typically from about 0.28 but less than 0.60 μm.

In addition, the average maximum pit depth (Rv) in the aluminum metal surface is less than or equal to 4.5 μm and typically from about 1.2 to about 4.5 μm.

While this electrochemically grained metal sheet can now be used in the method of this invention, it is usually subjected to additional treatments before such use. Generally, the electrochemically grained metal surface is etched with an alkaline solution to remove at least 100 mg/m², and typically to remove from about 100 to about 1000 mg/m². Etching can be carried out by immersing the metal sheet in a highly acidic solution or a highly alkaline solution having a pH of at least 13 and a conductivity of from about 30 to about 90 mS/cm. It is important to remove sufficient aluminum metal in order to change its optical density, which is directly related to the “smut” level on the surface of the aluminum sheet. The amount of aluminum metal removed is a function of concentration, temperature, and dwell time in the etching process. Thus, there are many combinations of these parameters that a skilled artisan can consider in routine experimentation to find the optimum etching conditions for removing at least 100 mg/m².

The electrochemically grained aluminum support can then be anodized in an alternating current passing through a sulfuric acid solution (5-30%) at a temperature of from about 20 to about 60° C. for from about 5 to about 250 seconds to form an oxide layer on the metal surface. When phosphoric acid is used for anodization, the conditions may be varied, as one skilled in the art would readily know. Generally, anodization is carried out to provide an oxide layer of at least 0.3 g/m² and typically from about 1.5 to about 4 g/m².

The aluminum-containing support is then treated to provide a hydrophilic interlayer to render its surface more hydrophilic by treatment with, for example, a post-treatment solution containing a homopolymer of vinyl phosphonic acid (PVPA) or a vinyl phosphonic acid copolymer such as a copolymer derived from vinyl phosphonic acid and (meth)acrylic acid (that is either methacrylic acid, acrylic acid, or both). Typically, the electrochemically grained, etched, and anodized aluminum support is treated with PVPA.

The aluminum support surface having an anodic oxide layer is treated with an aqueous post-treatment solution comprising a polymer derived from vinyl phosphonic acid and an Al⁺³ salt, wherein the concentration of the polymer is maintained in the post-treatment solution at a concentration of within ±50% of a target polymer concentration of from about 1.5×10⁻⁴ to about 1.5 mol phosphonic acid groups per liter, and the concentration of Al⁺³ is maintained in the same post-treatment solution at a concentration of within ±50% of target Al⁺³ concentration within the range of from about 1×10⁻⁶ to about 1×10⁻¹ mol/liter. This treatment step deposits at least 3×10⁻⁶ mole of phosphonic acid groups per m² of the support.

Typically, during the post-treatment step, the concentration of the noted polymer is maintained in the aqueous post-treatment solution at a concentration of within ±15% of a target polymer concentration within the range of from about 1.5×10⁻³ to about 1×10⁻¹ mol phosphonic acid groups per liter. In addition, the concentration of Al⁺³ is maintained at a concentration of within ±15% of target Al⁺³ concentration within the range of from about 1×10⁻⁵ to about 1×10⁻³ mol/liter.

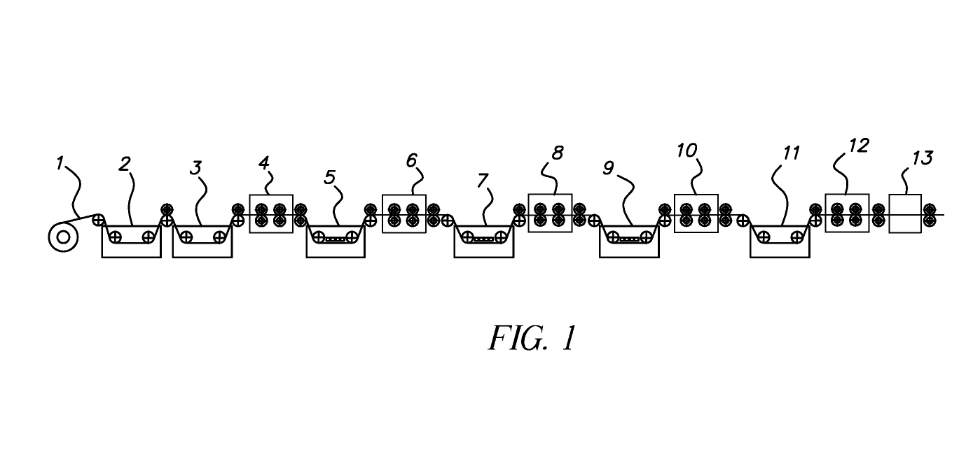

The aluminum support can be treated in various forms, but usually a continuous web of grained and anodized aluminum support is passed through the aqueous post-treatment solution at a rate sufficient to provide the desired layer of polymer on its surface. The process schematically shown in FIG. 1 is representative of a typical substrate manufacturing process using an aluminum support web.

During the post-treatment step in the present invention, aluminum (+3) concentration is maintained a target aluminum (+3) concentration instead of letting it continually increase, to provide optimum substrate performance. The conditions of concentration maintenance are outlined below.

In most embodiments, the aluminum support is immersed in the post-treatment solution for a suitable time to deposit the desired amount of hydrophilic polymer. Most of the discussion that follows relate more directly to this immersion mode of post-treatment. However, it is to be understand that some embodiments of the present invention can be carried out using a “spray” mode in which the post-treatment solution is delivered or applied to the aluminum support using one or more spray bars from a reservoir or recovery tank using a suitable fluid delivery system. The reservoir or recovery tank would then contain an appropriate amount of post-treatment solution in which the aluminum (+3) and hydrophilic polymer concentrations are controlled within ±50% of desired target concentrations using various means according to the present invention.

The target polymer concentration is chosen by determining the desired amount of polymer to be deposited on the aluminum support and the time during which the support is in the aqueous post-treatment solution. This can be done by routine experimentation or from standard specifications used in the art. The target polymer concentration and web dwell time in the post-treatment solution are chosen to deposit at least 3×10⁻⁶ mol phosphonic acid groups per m².

The target aluminum (+3) concentration can be determined by trying various concentrations in the aqueous post-treatment solution and evaluating the printability properties of the resulting substrate as part of imaged lithographic printing plates. This also can be done with routine experimentation and using the teaching provided in the Examples below.

The molar ratio of phosphonic acid group to Al⁺³ ion in the post-treatment solution is generally from about 1000:1 to about 1:10 (typically from about 10:1 to about 1:5), and the post-treatment solution has a pH of generally from about 1.5 to about 7 (typically from about 2 to about 4).

The post-treatment step is generally carried out at a temperature of from about 20 to about 80° C. (typically from about 40 to about 70° C.) while contacting the web for from about 1 to about 60 seconds (typically from about 5 to about 20 seconds).

The target concentration of the polymer can be maintained in the post-treatment solution by replenishing the post-treatment solution with one or more replenisher solutions, each at a given rate, to maintain, increase or decrease the polymer concentration, Al⁺³ concentration, or both concentrations.

Controlling the aluminum (+3) and phosphonic acid polymer concentrations at pre-selected target concentrations in the post-treatment solution may be carried out, for example, using the following steps:

1) A post-treatment solution is prepared with target Al⁺³ and polymer concentrations [Al⁺³]₁ and [polymer]₁, respectively.

2) A single combined or separate replenishment solutions are prepared with Al⁺³ and polymer concentrations [Al⁺³]₂ and [polymer]₂, respectively.

3) The aluminum substrate web having a given web width (W) is moved through the post-treatment solution at a predetermined web speed (S) that would be readily known to one skilled in the art.

4) Replenish the post-treatment solution with the single combined or separate replenishment solutions at a given rate (R) to keep the aluminum ion and polymer concentrations at [Al⁻³]₁ and [polymer]₁, respectively, within a variation of ±50% (typically ±15%) for each concentration.

Within this process, [Al⁺³]₂, [polymer]₂, and R can be readily determined by a skilled artisan with routine experimentation to reach generally constant aluminum ion and polymer concentrations in a “steady state” mode as aluminum web is processed over time. Alternatively, a skilled artisan can calculate the desired [Al⁺³]₂, [polymer]₂, and R from a calculation of the desired deposition of polymer onto the aluminum web (that is, the loss of polymer from the post-treatment solution) as well as a calculation of the amount of aluminum ion entering the post-treatment solution.

Alternatively, post-treatment solution target concentrations [Al⁻³]₁ and [polymer]₁ can be measured during treatment of the aluminum web and maintained by adding one or more of the following replenishment solutions at pre-determined rates:

a) A solution having the [polymer]₁ but also having an aluminum ion concentration of 0 or substantially lower than [Al⁺³]₁ to reduce the post-treatment solution aluminum ion concentration to [Al⁺³]₁.

b) A solution having the [polymer]₁ but also having an aluminum ion concentration substantially higher than [Al⁻³]₁ to increase the post-treatment solution aluminum ion concentration to [Al⁺³]₁.

c) A solution having the [Al⁺³]₁ but also having a polymer concentration substantially higher than [polymer]₁ to increase the polymer concentration to [polymer]₁.

An aluminum replenishment solution can be made up to a desired aluminum (+3) salt concentration using one or more aluminum (+3) salts including but at not limited to, aluminum sulfate hydrated, aluminum chloride hydrated, aluminum bromide hydrated, and aluminum nitrate hydrated.

A polymer replenishment solution can be made up by dissolving the desired amount of polymer in water.

While the target polymer and aluminum (+3) concentrations can be maintained using individual replenisher solutions, it is also possible to combine those components in a single combined replenisher solution that is brought into the post-treatment solution.

The other noted solutions a), b), and c) can be easily made up using the appropriate amounts of aluminum salt and/or polymer.

While the replenishment solutions described herein are typically used in a continuous manner, they can also be used intermittently, that is, as needed during the treatment of an aluminum web. Alternatively, some replenishment solutions (such as the polymer replenishment solution) may be used continuously while other replenishment solutions (such as the aluminum ion replenishment solution) may be used intermittently.

The backside (non-imaging side) of an aluminum substrate may be coated with antistatic agents and/or slipping layers or a matte layer to improve handling and “feel” of the imageable element.

Imageable Elements

The substrates of this invention can be used to prepare a wide variety of imageable elements including negative- and positive-working imageable elements that can be imaged and processed for use as lithographic printing plates. Such imageable elements generally lithographic printing plate precursors and include one or more ink-receptive layers disposed on the substrate. That is, they include one or more imageable layers besides any layers generally used as subbing layers, adhesion layers, protective cover layers, or for other non-imaging purposes.

The imageable layers (hence elements) can be made sensitive to any suitable imaging radiation including UV, visible, and infrared radiation having a maximum exposure wavelength of from about 150 to about 1500 nm. The imageable elements can be designed for imaging on a variety of apparatus and for development either off-press using conventional developer solutions or on-press using fountain solutions, printing inks, or a mixture thereof.

For example, there are numerous publications in the art relating to negative-working imageable compositions and elements that can be used in the practice of this invention. Some of those useful compositions are photosensitive and based on the use of naphthoquinonediazides, diazo resins, photosensitive polymers, or thermally-switchable polymers (that is thermally switching polymer layers from hydrophobic to hydrophilic, or vice versa).

Other useful negative-working compositions generally include a polymerizable component (such as a free-radically polymerizable monomer, oligomer, or polymer, or acid-crosslinked compound), an initiator composition (such as compounds that generate free radicals, or promote cationically or acid-catalyzed polymerization or crosslinking), appropriate sensitizers or radiation absorbing compounds for a specific radiation sensitivity (also known as photothermal conversion materials) such as carbon blacks, IR dyes, coumarins, onium salts, triazines, metallocenes, polycarboxylic acids, hexaaryl bisimidazoles, and borate salts. Of these compositions, the IR-sensitive compositions are preferred.

Some particularly useful negative-working imageable compositions and elements with which the present invention can be used include but are not limited to, those described in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. No. 4,511,645 (Koike et al.), U.S. Pat. No. 6,027,857 (Teng), U.S. Pat. No. 6,309,792 (Hauck et al.), U.S. Pat. No. 6,569,603 (Furukawa et al.), U.S. Pat. No. 6,899,994 (Huang et al.), U.S. Pat. No. 7,045,271 (Tao et al.), and U.S. Pat. No. 7,049,046 (Tao et al.), and U.S. Patent Application Publications 2003/0064318 (Huang et al.), 2004/0265736 (Aoshima et al.), 2005/0266349 (Van Damme et al.), and 2006/0019200 (Vermeersch et al.). Other negative-working compositions and elements are described for example in Japanese Kokai 2000-187322 (Takasaki), 2001-330946 (Saito et al.), 2002-040631 (Sakurai et al.), 2002-341536 (Miyamoto et al.), and 2006-317716 (Hayashi).

The imageable elements of the invention can also be single- or multi-layer, thermally-sensitive, positive-working imageable elements that generally rely on a radiation absorbing compound dispersed within one or more polymeric binders that, upon suitable irradiation, are soluble, dispersible, or removable in alkaline developers, of which there are numerous examples in the art. Thus, the imageable layer, upon irradiation, undergoes a change in solubility properties with respect to the alkaline developer in its irradiated (exposed) regions.

For example, “single-layer” positive-working imageable elements are described for example, in WO 2004/081662 (Memetea et al.), U.S. Pat. No. 6,255,033 (Levanon et al.) and U.S. Pat. No. 6,541,181 (Levanon et al.), EP 1,627,732 (Hatanaka et al.), and US Published Patent Applications 2005/0214677 (Nagashima), 2004/0013965 (Memetea et al.), 2005/0003296 (Memetea et al.), and 2005/0214678 (Nagashima),

Other embodiments include imageable elements that comprise an aluminum-containing substrate (provided according to this invention), an inner layer (also known as an “underlayer”), and an ink-receptive outer layer (also known as a “top layer” or “topcoat”) disposed over the inner layer. Before thermal imaging, the outer layer is generally not soluble, dispersible, or removable by an alkaline developer within the usual time allotted for development, but after thermal imaging, the imaged regions of the outer layer are more readily removable by or dissolvable in the alkaline developer. The inner layer is also generally removable by the alkaline developer. An infrared radiation absorbing compound (defined below) is also present in the imageable element, and is typically present in the inner layer but may optionally be in a separate layer between the inner and outer layers.

Thermally imageable, multi-layer elements are described, for example, in U.S. Pat. No. 6,294,311 (Shimazu et al.), U.S. Pat. No. 6,352,812 (Shimazu et al.), U.S. Pat. No. 6,593,055 (Shimazu et al.), U.S. Pat. No. 6,352,811 (Patel et al.), U.S. Pat. No. 6,358,669 (Savariar-Hauck et al.), and U.S. Pat. No. 6,528,228 (Savariar-Hauck et al.), U.S. Patent Application Publications 2004/0067432 A1 (Kitson et al.) and 2005/0037280 (Loccufier et al.).

The inner layer is disposed between the outer layer and the substrate. Typically, it is disposed directly on the substrate. The inner layer comprises a predominant first polymeric material that is removable by the developer and preferably soluble in the developer to reduce sludging of the developer. In addition, this first polymeric material is preferably insoluble in the solvent used to coat the outer layer so that the outer layer can be coated over the inner layer without dissolving the inner layer. This polymeric material is also identified herein as the “first polymeric binder” so as to distinguish it from the “second polymeric binder” described below for the outer layer. Mixtures of these first polymeric binders can be used if desired in the inner layer.

Useful first polymeric binders for the inner layer include but are not limited to, (meth)acrylonitrile polymers, (meth)acrylic resins comprising pendant carboxy groups, polyvinyl acetals, maleated wood rosins, styrene-maleic anhydride copolymers, (meth)acrylamide polymers such as polymers derived from N-alkoxyalkyl methacrylamide, polymers derived from an N-substituted cyclic imide, polymers having pendant urea or cyclic urea groups, and combinations thereof. First polymeric binders that provide resistance both to fountain solution and aggressive washes are disclosed in U.S. Pat. No. 6,294,311 (noted above) that is incorporated herein by reference.

Particularly useful first polymeric binders include (meth)acrylonitrile polymers, and polymers derived from an N-substituted cyclic imide (especially N-phenylmaleimide), a (meth)acrylamide (especially methacrylamide), a monomer having a pendant urea or cyclic urea group, and a (meth)acrylic acid (especially methacrylic acid). First polymeric binders of this type are copolymers that comprise from about 20 to about 75 mol % of recurring units derived from N-phenylmaleimide, N-cyclohexylmaleimide, N-(4-carboxyphenyl)maleimide, N-benzylmaleimide, or a mixture thereof, from about 10 to about 50 mol % of recurring units derived from acrylamide, methacrylamide, or a mixture thereof, and from about 5 to about 30 mol % of recurring units derived from methacrylic acid. Other hydrophilic monomers, such as hydroxyethyl methacrylate, may be used in place of some or all of the methacrylamide. Other alkaline soluble monomers, such as acrylic acid, may be used in place of some or all of the methacrylic acid. Optionally, these polymers can also include recurring units derived from (meth)acrylonitrile or N-[2-(2-oxo-1-imidazolidinyl)ethyl]-methacrylamide.

The bakeable inner layers described in WO 2005/018934 (Kitson et al.) and U.S. Pat. No. 6,893,783 (Kitson et al.) may also be used.

Other useful first polymeric binders can comprise, in polymerized form, from about 5 mol % to about 30 mol % of recurring units derived from an ethylenically unsaturated polymerizable monomer having a carboxy group (such as acrylic acid, methacrylic acid, itaconic acid, and other similar monomers known in the art (acrylic acid and methacrylic acid are preferred), from about 20 mol % to about 75 mol % of recurring units derived from N-phenylmaleimide, N-cyclohexylmaleimide, or a mixture thereof, optionally, from about 5 mol % to about 50 mol % of recurring units derived from methacrylamide, and from about 3 mol % to about 50 mol % of one or more recurring units derived from monomer compounds of the following Structure (I):

CH₂═C(R₂)—C(═O)—NH—CH₂—OR₁ (I)

wherein R₁ is a C₁ to C₁₂ alkyl, phenyl, C₁ to C₁₂ substituted phenyl, C₁ to C₁₂ aralkyl, or Si(CH₃)₃, and R₂ is hydrogen or methyl. Methods of preparation of certain of these polymeric materials are disclosed in U.S. Pat. No. 6,475,692 (Jarek).

The first polymeric binder useful in this invention can also be hydroxy-containing polymeric material composed of recurring units derived from two or more ethylenically unsaturated monomers wherein from about 1 to about 50 mol % of the recurring units are derived from one or more of the monomers represented by the following Structure (II):

CH₂═C(R₃)C(═O)NR₄(CR₅R₆)ₘOH (II)

wherein R₃, R₄, R₅, R₆ are independently hydrogen, substituted or unsubstituted lower alkyl having 1 to 10 carbon atoms (such as methyl, chloromethyl, ethyl, iso-propyl, t-butyl, and n-decyl), or substituted or unsubstituted phenyl, and m is 1 to 20.

Useful embodiments of hydroxy-containing first polymeric binders can be represented by the following Structure (III):

-(A)ₓ-(B)_{y}-(C)_{z}- (III)

wherein A represents recurring units represented by the following Structure (IV):

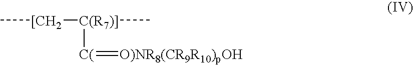

wherein R₇ through R₁₀ and p are as defined the same as R₃ through R₆ and m noted above for Structure (II).

In Structure (IV), B represents recurring units comprising acidic functionality or an N-maleimide group, and C represents recurring units different from A and B, x is from about 1 to about 50 mol %, y is from about 40 to about 90 mol %, and z is 0 to about 70 mol %, based on total recurring units.

In some embodiments of Structure (IV):

A represents recurring units derived from one or both of N-hydroxymethylacrylamide and N-hydroxymethylmethacrylamide,

B represents recurring units derived from one or more of N-phenylmaleimide, N-cyclohexylmaleimide, N-benzylmaleimide, N-(4-carboxyphenyl)maleimide, (meth)acrylic acid, and vinyl benzoic acid, and

C represents recurring units derived from one or more of a styrenic monomer (such as styrene and derivatives thereof), meth(acrylate) ester, N-substituted (meth)acrylamide, maleic anhydride, (meth)acrylonitrile, allyl acrylate, and a compound represented by the following Structure (V):

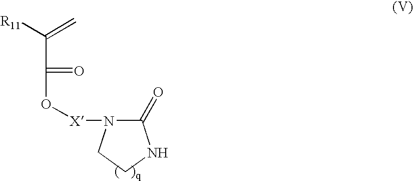

wherein R₁₁ is hydrogen, methyl, or halo, q is 1 to 3, X′ is alkylene having 2 to 12 carbon atoms, x is from about 10 to about 40 mol %, y is from about 40 to about 70 mol %, and z is from 0 to about 50 mol %, all based on total recurring units.

In other embodiments for Structure III, B represents recurring units derived from one of N-phenylmaleimide, N-cyclohexylmaleimide, N-benzylmaleimide, N-(4-carboxyphenyl)maleimide in an amount of from about 20 to about 50 mol %, and recurring units derived from one of (meth)acrylic acid and vinyl benzoic acid in an amount of from about 10 to about 30 mol %, based on total recurring units.

In such embodiments, C represents recurring units derived from methacrylamide, (meth)acrylonitrile, maleic anhydride, or

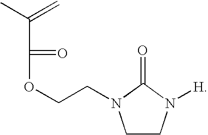

Still other useful first polymeric binders are addition or condensation polymers that have a polymer backbone having attached pendant phosphoric acid groups, pendant adamantyl groups, or both types of pendant groups. The pendant adamantyl groups are connected to the polymer backbone from about through a urea or urethane linking group but other linking groups can also be present.

First polymeric binders of this type can be represented by the following Structure (VI):

-(A)ₓ-(B)_{y}- (VI)

wherein A and B together represents the polymer backbone in which A further comprises recurring units comprising pendant phosphoric acid groups, pendant adamantyl groups, or both, B further represents different recurring units, x represents from about 5 to about 100 weight %, and y represents 0 to about 95 weight %, provided that if A comprises pendant adamantyl groups, such groups are connected to the polymer backbone through a urea or urethane linking group (but other linking groups can also be present).

Such first polymeric binders can be represented by the following Structure (VII):

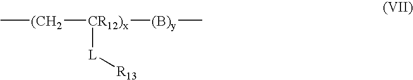

wherein R₁₂ represents hydrogen, a substituted or unsubstituted lower alkyl group having 1 to 4 carbon atoms (such as methyl, ethyl, n-propyl, or t-butyl), or a halo group.

L represents a direct bond or a linking group comprising 1 or more carbon atoms and optionally 1 or more heteroatoms in the linking chain. Useful linking groups can include, but are not limited to, substituted or unsubstituted, linear or branched alkylene groups having 1 to 10 carbon atoms (such as methylene, methoxymethylene, ethylene, iso-propylene, n-butylene, t-butylene, and n-hexylene), substituted or unsubstituted cycloalkylene groups having 5 to 10 carbon atoms in the cyclic group (such as 1,3-cyclopentylene and 1,4-cyclohexylene), substituted or unsubstituted arylene groups having 6 to 10 carbon atoms in the cyclic group (such as 1,4-phenylene, 3-methyl-1,4-phenylene, or naphthylene), or combinations thereof, such as arylenealkylene, alkylenearylene, and alkylenearylenealkylene groups. The L linking groups can also include one or more oxy, thio, amido, carbonyl, oxycarbonyl, carbonyloxy, carbonamido, sulfonamido, urea, urethane, and carbonate [—O—C(═O)—O—] groups within the linking chain, with or without any of the alkylene, cycloalkylene, and arylene groups described above. L can include combinations of two or more of these groups.

In Structure (VII), R₁₃ represents a pendant phosphoric acid group, a pendant adamantyl group, or both types of pendant groups. The solvent-resistant polymer can comprise one or more different recurring units having phosphoric acid groups or one or more different recurring units having adamantyl groups. Alternatively, the polymer can include a mixture of one or more different recurring units having phosphoric acid groups and one or more different recurring units having adamantyl groups. When R₁₃ is a pendant adamantyl group, L comprises a urea or urethane linking group within the linking chain.

In referring to “phosphoric acid” groups, it is also intended to include the corresponding salts of the phosphoric acid, including but not limited to, alkali metal salts and ammonium salts. Any suitable positive counterion can be used with the pendant phosphoric acid groups as long as the counterion does not adversely affect the performance of the resulting polymer or other desired imaging properties.

In Structures VI and VII, x is from about 5 to about 20 weight % and y is from about 80 to about 95 weight % when A represents recurring units comprising pendant phosphoric acid groups. Alternatively, x is from about 5 to about 40 weight % and B is from about 60 to about 95 weight % when A represents recurring units comprising pendant adamantyl groups.

In Structures (VI) and (VII), B represents recurring units derived from one or more ethylenically unsaturated polymerizable monomers that do not have pendant phosphoric acid groups or adamantyl groups. A variety of monomers can be used for providing B recurring units, including styrenic monomers, (meth)acrylamide, (meth)acrylic acids or esters thereof, (meth)acrylonitrile, vinyl acetate, maleic anhydride, N-substituted maleimide, or mixtures thereof.

Preferably, the recurring units represented by B are derived from styrene, N-phenylmaleimide, methacrylic acid, (meth)acrylonitrile, or methyl methacrylate, or mixtures of two or more of these monomers.

In some embodiments, the first polymeric binder can be represented by Structure (VI) described above in which x is from about 5 to about 30 weight % and B represents recurring units derived from:

a) one or more of styrene, N-phenylmaleimide, methacrylic acid, and methyl methacrylate, wherein these recurring units comprise from 0 to about 70 weight % of all recurring units in the solvent-resistant polymer, and

b) one or more of acrylonitrile or methacrylonitrile, or mixtures thereof, wherein these recurring units comprise from about 20 to about 95 weight % of all recurring units in the solvent-resistant polymer.

Other useful first polymeric binders comprise a backbone and have attached to the backbone the following Structure Q group:

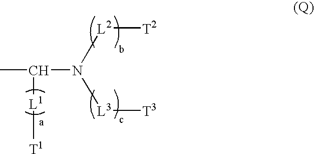

wherein L¹, L², and L³ independently represent linking groups, T¹, T², and T³ independently represent terminal groups, and a, b, and c are independently 0 or 1.

More particularly, each of L¹, L², and L³ is independently a substituted or unsubstituted alkylene having 1 to 4 carbon atoms (such as methylene, 1,2-ethylene, 1,1-ethylene, n-propylene, iso-propylene, t-butylene, and n-butylene groups), substituted cycloalkylene having 5 to 7 carbon atoms in the cyclic ring (such as cyclopentylene and 1,4-cyclohexylene), substituted or unsubstituted arylene having 6 to 10 carbon atoms in the aromatic ring (such as 1,4-phenylene, naphthylene, 2-methyl-1,4-phenylene, and 4-chloro-1,3-phenylene groups), or substituted or unsubstituted, aromatic or non-aromatic divalent heterocyclic group having 5 to 10 carbon and one or more heteroatoms in the cyclic ring (such as pyridylene, pyrazylene, pyrimidylene, or thiazolylene groups), or any combinations of two or more of these divalent linking groups. Alternatively, L² and L³ together can represent the necessary atoms to form a carbocyclic or heterocyclic ring structure. Preferably, L¹ is a carbon-hydrogen single bond or a methylene, ethylene, or phenylene group, and L² and L³ are independently hydrogen, methyl, ethyl, 2-hydroxyethyl, or cyclic —(CH₂)₂O(CH₂CH₂)— groups.

T¹, T², and T³ are independently terminal groups such as hydrogen, or substituted or unsubstituted alkyl groups having 1 to 10 carbon atoms (such as methyl, ethyl, iso-propyl, t-butyl, n-hexyl, methoxymethyl, phenylmethyl, hydroxyethyl, and chloroethyl groups), substituted or unsubstituted alkenyl groups having 2 to 10 carbon atoms (such as ethenyl and hexenyl groups), substituted or unsubstituted alkynyl groups (such as ethynyl and octynyl groups), substituted or unsubstituted cycloalkyl groups having 5 to 7 carbon atoms in the cyclic ring (such as cyclopentyl, cyclohexyl, and cycloheptyl groups), substituted or unsubstituted heterocyclic groups (both aromatic and non-aromatic) having a carbon atom and one or more heteroatoms in the ring (such as pyridyl, pyrazyl, pyrimidyl, thiazolyl, and indolyl groups), and substituted or unsubstituted aryl groups having 6 to 10 carbon atoms in the aromatic ring (such as phenyl, naphthyl, 3-methoxyphenyl, benzyl, and 4-bromophenyl groups). Alternatively, T² and T³ together represent the atoms necessary to form a cyclic structure that can also contain fused rings. In addition, when “a” is 0, T³ is not hydrogen.

In some embodiments, the Structure Q group can be directly attached to an a-carbon atom in the polymer backbone, the α-carbon atom also having attached thereto an electron withdrawing group. In other embodiments, the Structure Q group is indirectly attached to the polymer backbone through a linking group.

The first polymeric binders can also be represented by the following Structure (VIII):

-(A)ₓ-(B)_{y}- (VIII)

wherein A represents recurring units derived from one or more ethylenically unsaturated polymerizable monomers that comprise the same or different Q groups, B represents recurring units derived from one or more different ethylenically unsaturated polymerizable monomers that do not comprise Q groups.

More particularly, the A recurring units in Structure VIII can be represented by the following Structure (VIIIa) or (VIIIb):

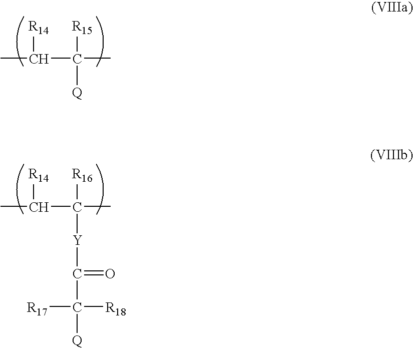

wherein R₁₄ and R₁₆ are independently hydrogen or a halo, substituted or unsubstituted alkyl having 1 to 7 carbon atoms (such as methyl, ethyl, n-propyl, iso-propyl, or benzyl), or a substituted or unsubstituted phenyl group. Preferably, R₁₄ and R₁₆ are independently hydrogen or a methyl or halo group, and more preferably they are independently hydrogen or methyl.

R₁₅ in Structure VIIIa is an electron withdrawing group as defined above including but are not limited to, cyano, nitro, substituted or unsubstituted aryl groups having 6 to 10 carbon atoms in the carbocyclic ring, substituted or unsubstituted heteroaryl groups having 5 to 10 carbon, sulfur, oxygen, or nitrogen atoms in the heteroaromatic ring, —C(═O)OR₂₀, and —C(═O)R₂₀ groups wherein R₂₀ is hydrogen or a substituted or unsubstituted alkyl having 1 to 4 carbon atoms (such as methyl, ethyl, n-propyl, t-butyl), a substituted or unsubstituted cycloalkyl (such as a substituted or unsubstituted cyclohexyl), or a substituted or unsubstituted aryl group (such as substituted or unsubstituted phenyl). The cyano, nitro, —C(═O)OR₂₀, and —C(═O)R₂₀ groups are preferred and cyano, —C(═O)CH₃, and —C(═O)OCH₃ are most preferred.

R₁₇ and R₁₈ in Structure (VIIIb) are independently hydrogen or a substituted or unsubstituted alkyl group having 1 to 6 carbon atoms (such as such as methyl, ethyl, n-propyl, t-butyl, n-hexyl), substituted or unsubstituted cycloalkyl having 5 or 6 carbon atoms (such as cyclohexyl), a substituted or unsubstituted aryl group having 6 to 10 carbon atoms (such as phenyl, 4-methylphenyl, and naphthyl), or a —C(═O)R₁₉ group wherein R₁₉ is a substituted or unsubstituted alkyl group (as defined for R₁₇ and R₁₈), a substituted or unsubstituted alkenyl group having 2 to 8 carbon atoms (such as ethenyl and 1,2-propenyl), a substituted or unsubstituted cycloalkyl group (as defined above for R₁₇ and R₁₈), or a substituted or unsubstituted aryl group (as defined above for R₁₇ and R₁₈). Preferably, R₁₇ and R₁₈ are independently hydrogen or a substituted or unsubstituted alkyl, cycloalkyl, aryl, or —C(═O)R₁₉ groups as defined above wherein R₁₉ is an alkyl having 1 to 4 carbon atoms.

In Structure (VIIIb), Y is a direct bond or a divalent linking group. Useful divalent linking groups include but are not limited to oxy, thio, —NR₂₁—, substituted or unsubstituted alkylene, substituted or unsubstituted phenylene, substituted or unsubstituted heterocyclylene, —C(═O)—, and —C(═O)O— groups, or a combination thereof wherein R₂₁ is hydrogen or a substituted or unsubstituted alkyl, substituted or unsubstituted cycloalkyl, or substituted or unsubstituted aryl group, as defined above for R₁₇ and R₁₈. Preferably, Y is a direct bond or an oxy, —C(═O)O—, —C(═O)OCH₂CH₂O—, or —C(═O)CH₂CH₂OC(═O)CH₂— group.

In Structure (VIII), x is from about 1 to about 70 mol %, and y is from about 30 to about 99 mol %, based on total recurring units. Preferably, x is from about 5 to about 50 mol % and y is from about 50 to about 95 mol %, based on total recurring units.

Also in Structure (VIII), B can represent recurring units derived from a wide variety of ethylenically unsaturated polymerizable monomers. Particularly useful recurring units are derived from one or more N-substituted maleimides, N-substituted (meth)acrylamides, unsubstituted (meth)acrylamides, (meth)acrylonitriles, or vinyl monomers having an acidic group, and more preferably from one or more N-phenylmaleimides, N-cyclohexylmaleimides, N-benzylmaleimides, N-(4-carboxyphenyl)maleimides, (meth)acrylic acids, vinyl benzoic acids, (meth)acrylamides, and (meth)acrylonitriles. Several of these monomers can be copolymerized to provide multiple types of B recurring units. Particularly useful combinations of B recurring units include those derived from two or more of methacrylic acid, methacrylamide, and N-phenylmaleimide.

The first polymeric binders are the predominant polymeric materials in the inner layer. That is, they comprise from about 50% to about 100% (dry weight) of the total polymeric materials in the inner layer. However, the inner layer may also comprise one or more primary additional polymeric materials, provided these primary additional polymeric materials do not adversely affect the chemical resistance and solubility properties of the inner layer.

Useful primary additional polymeric materials include copolymers that comprises from about 1 to about 30 mole % of recurring units derived from N-phenylmaleimide, from about 1 to about 30 mole % of recurring units derived from methacrylamide, from about 20 to about 75 mole % of recurring units derived from acrylonitrile, and from about 20 to about 75 mole % of recurring units derived from one or more monomers of the Structure (IX):

CH₂═C(R₂₃)—CO₂—CH₂CH₂—NH—CO—NH-p-C₆H₄—R₂₂ (IX)

wherein R₂₂ is OH, COOH, or SO₂NH₂, and R₂₃ is H or methyl, and, optionally, from about 1 to about 30 mole % and, when present, from about 3 to about 20 mole % of recurring units derived from one or more monomers of the Structure (X):

CH₂═C(R₂₅)—CO—NH-p-C₆H₄R₂₄ (X)

wherein R₂₄ is OH, COOH, or SO₂NH₂, and R₂₅ is H or methyl.

The inner layer may also comprise one or more secondary additional polymeric materials that are resins having activated methylol and/or activated alkylated methylol groups. These “secondary additional polymeric materials” in the inner layer should not be confused as the “second polymeric binder” used in the outer layer.

The secondary additional polymeric materials can include, for example resole resins and their alkylated analogs, methylol melamine resins and their alkylated analogs (for example melamine-formaldehyde resins), methylol glycoluril resins and alkylated analogs (for example, glycoluril-formaldehyde resins), thiourea-formaldehyde resins, guanamine-formaldehyde resins, and benzoguanamine-formaldehyde resins. Commercially available melamine-formaldehyde resins and glycoluril-formaldehyde resins include, for example, CYMEL® resins (Dyno Cyanamid) and NIKALAC® resins (Sanwa Chemical).

The resin having activated methylol and/or activated alkylated methylol groups is preferably a resole resin or a mixture of resole resins. Resole resins are well known to those skilled in the art. They are prepared by reaction of a phenol with an aldehyde under basic conditions using an excess of phenol. Commercially available resole resins include, for example, GP649D99 resole (Georgia Pacific) and BKS-5928 resole resin (Union Carbide).

Useful secondary additional polymeric materials can also include copolymers that comprise from about 25 to about 75 mole % of recurring units derived from N-phenylmaleimide, from about 10 to about 50 mole % of recurring units derived from methacrylamide, and from about 5 to about 30 mole % of recurring units derived from methacrylic acid. These secondary additional copolymers are disclosed in U.S. Pat. No. 6,294,311 (Shimazu et al.) and U.S. Pat. No. 6,528,228 (Savariar-Hauck et al.).

The first polymeric binder and the primary and secondary additional polymeric materials useful in the inner layer can be prepared by methods, such as free radical polymerization, that are well known to those skilled in the art and that are described, for example, in Chapters 20 and 21, of Macromolecules, Vol. 2, 2nd Ed., H. G. Elias, Plenum, N.Y., 1984. Useful free radical initiators are peroxides such as benzoyl peroxide, hydroperoxides such as cumyl hydroperoxide and azo compounds such as 2,2′-azobis(isobutyronitrile) (AIBN). Suitable reaction solvents include liquids that are inert to the reactants and that will not otherwise adversely affect the reaction.

In some embodiments, the inner layer (and preferably only the inner layer) further comprises an infrared radiation absorbing compound (“IR absorbing compounds”) that absorbs radiation from about at 600 nm to about 1500 and typically from about at 700 nm to about 1200 nm, with minimal absorption at from about 300 to about 600 nm. This compound (sometimes known as a “photothermal conversion material”) absorbs radiation and converts it to heat. Although one of the polymeric materials may itself comprise an IR absorbing moiety, typically the infrared radiation absorbing compound is a separate compound. This compound may be either a dye or pigments such as iron oxides and carbon blacks. Examples of useful pigments are ProJet 900, ProJet 860 and ProJet 830 (all available from the Zeneca Corporation).

Useful infrared radiation absorbing compounds also include carbon blacks including carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful.

IR absorbing dyes (especially those that are soluble in an alkaline developer) are desired to prevent sludging of the developer by insoluble material. Examples of suitable IR dyes include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indoaniline dyes, merostyryl dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in numerous publications including U.S. Pat. No. 6,294,311 (noted above) and U.S. Pat. No. 5,208,135 (Patel et al.) and the references cited thereon.

Examples of useful IR absorbing compounds include ADS-830A and ADS-1064 (American Dye Source, Baie D'Urfe, Quebec, Canada), EC2117 (FEW, Wolfen, Germany), Cyasorb® IR 99 and Cyasorb® IR 165 (GPTGlendale Inc. Lakeland, Fla.), and IR Absorbing Dye A used in the Examples below.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanate et al.). Suitable dyes may be formed using conventional methods and starting materials or obtained from various commercial sources including American Dye Source (Canada) and FEW Chemicals (Germany). Other useful dyes for near infrared diode laser beams are described, for example, in U.S. Pat. No. 4,973,572 (DeBoer).

In addition to low molecular weight IR-absorbing dyes, IR dye moieties bonded to polymers can be used as well. Moreover, IR dye cations can be used, that is, the cation is the IR absorbing portion of the dye salt that ionically interacts with a polymer comprising carboxy, sulfo, phosphor, or phosphono groups in the side chains.

The infrared radiation absorbing compound can be present in the imageable element in an amount of generally from about 5% to about 30% and typically from about 12 to about 25%, based on the total dry weight of the element. This amount is based on the total dry weight of the layer in which it is located.

The inner layer can include other components such as surfactants, dispersing aids, humectants, biocides, viscosity builders, drying agents, defoamers, preservatives, antioxidants, and colorants.

The inner layer generally has a dry coating coverage of from about 0.5 to about 2.5 g/m². The first polymeric binders described above generally comprise from about 50 weight % and typically from about 60 to about 90 weight % based on the total dry layer weight, and this amount can be varied depending upon what other polymers and chemical components are present. Any primary and secondary additional polymeric materials (such as a novolak, resole, or copolymers noted above) can be present in an amount of from about 5 to about 45 weight % based on the total dry weight of the inner layer.

The ink-receptive outer layer of the imageable element is disposed over the inner layer and in preferred embodiments there are no intermediate layers between the inner and outer layers. The outer layer comprises a second polymeric material that is different than the first polymeric binder described above. The outer layer is substantially free of infrared radiation absorbing compounds, meaning that none of these compounds are purposely incorporated therein and insubstantial amounts diffuse into it from other layers.

Thus, the outer layer comprises a second polymeric binder that is a light-stable, water-insoluble, alkaline developer soluble, film-forming binder material such as phenolic resins, urethane resins, and polyacrylates. Particularly useful binder materials are described, for example in U.S. Pat. No. 6,352,812 (noted above), U.S. Pat. No. 6,358,669 (noted above), U.S. Pat. No. 6,352,811 (noted above), U.S. Pat. No. 6,294,311 (noted above), U.S. Pat. No. 6,893,783 (Kitson et al.), and U.S. Pat. No. 6,645,689 (Jarek), U.S. Patent Application Publications 2003/0108817 (Patel et al) and 2003/0162126 (Kitson et al.), and WO 2005/018934 (Kitson et al.).

Other useful film-forming second polymeric binders for the outer layer are phenolic resins or hydroxy-containing polymers containing phenolic monomeric units that can be random, alternating, block, or graft copolymers of different monomers and may be selected from polymers of vinyl phenol, novolak resins, or resole resins.

Useful poly(vinyl phenol) resins can be polymers of one or more hydroxyphenyl containing monomers such as hydroxystyrenes and hydroxyphenyl (meth)acrylates. Other monomers not containing hydroxy groups can be copolymerized with the hydroxy-containing monomers. These resins can be prepared by polymerizing one or more of the monomers in the presence of a radical initiator or a cationic polymerization initiator using known reaction conditions.

Examples of useful hydroxy-containing polymers include ALNOVOL SPN452, SPN400, HPN100 (Clariant GmbH), DURITE PD443, SD423A, SD126A, PD494A, PD-140 (Hexion Specialty Chemicals, Columbus, Ohio), BAKELITE 6866LB02, AG, 6866LB03 (Bakelite AG), KR 400/8 (Koyo Chemicals Inc.), HRJ 1085 and 2606 (Schenectady International, Inc.), and Lyncur CMM (Siber Hegner), all of which are described in U.S. Patent Application Publication 2005/0037280 (noted above).

Useful novolak resins in the upper layer can be non-functionalized, or functionalized with polar groups including but not limited to, diazo groups, carboxylic acid esters (such as acetate benzoate), phosphate esters, sulfinate esters, sulfonate esters (such as methyl sulfonate, phenyl sulfonate, tosylate, 2-nitrobenzene tosylate, and p-bromophenyl sulfonate), and ethers (such as phenyl ethers). The phenolic hydroxyl groups can be converted to -T-Z groups in which “T” is a polar group and “Z” is another non-diazide functional group (as described for example in WO 99/01795 of McCullough et al. and U.S. Pat. No. 6,218,083 of McCullough et al.). The phenolic hydroxyl groups can also be derivatized with diazo groups containing o-naphthoquinone diazide moieties (as described for example in U.S. Pat. Nos. 5,705,308 and 5,705,322 both of West et al.).

It is also possible to include in the outer layer one or more “modified” phenolic resin binders that comprise phenolic recurring units that are substituted by the group represented by Structure (Q) shown above for the polymeric binders useful in the inner layer. Thus, the inner and outer layers can comprise the same or different “modified” phenolic resin binder.

Other useful second polymeric binders include copolymers of maleic anhydride and styrene or a substituted styrene or a mixture of styrene monomers. The maleic anhydride generally comprises from about 1 to about 50 mol % of the copolymer. Additional monomers, such as (meth)acrylates, and (meth)acrylonitriles, (meth)acrylamides can also be used to provide recurring units within the copolymers.

Still other useful second polymeric binders include copolymers of one or more (meth)acrylates and one or more monomers containing a carboxy group and having 14 or less carbon atoms. Examples of useful (meth)acrylates include but are not limited to, methyl acrylate, methyl methacrylate, ethyl acrylate, ethyl methacrylate, n-butyl acrylate, and n-butyl methacrylate. Useful monomers having a carboxy group include but are not limited to, acrylic acid, methacrylic acid, 3-vinyl benzoic acid, 4-vinyl benzoic acid, itaconic acid, maleic acid, and monomers formed from the reaction of a hydroxyl-containing monomer (such as 2-hydroxyethyl acrylate and 2-hydroxyethyl methacrylate) and a cyclic anhydride (such as succinic anhydride or phthalic anhydride). The molar ratio of the (meth)acrylate monomer(s) to the carboxy-containing monomer(s) is generally from about 80:20 to about 98:2. Such copolymers can also include recurring units derived from one or more of maleic anhydride, vinyl ethers, (meth)acrylonitriles, and (meth)acrylamides.

Still more useful second polymeric binders are the copolymers described in U.S. Patent Application Publication 2004/0137366 (Kawauchi et al.) that comprise pendant carboxy groups directly or indirectly attached to the polymer backbone.

The second polymeric binder can also comprises recurring units having pendant carboxy groups that are generally represented by the following Structure (XI) or (XII), which recurring units comprise from about 3 mol % of the total recurring units in the second polymeric binder:

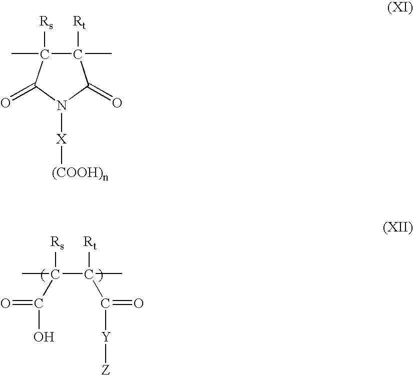

wherein n is 1 to 3 (preferably 1 or 2 and more preferably 1).

In Structure (XI) or (XII), Rₛ and Rₜ are independently hydrogen or a substituted or unsubstituted alkyl group having 1 to 7 carbon atoms (such as methyl, ethyl, t-butyl, or benzyl), or a halo group (such as chloro or bromo). Preferably, Rₛ and Rₜ are independently hydrogen or a substituted or unsubstituted methyl group or chloro group, and more preferably, they are independently hydrogen or a methyl group.

X is a multivalent linking group including but not limited to multivalent aliphatic and aromatic linking groups, and combinations thereof. In most embodiments, X is a divalent linking group. Such groups can include alkylene, arylene, alkylenearylene, arylenealkylene, alkyleneoxyalkylene, aryleneoxyarylene, and alkyleneoxyarylene groups, all of which can be unsubstituted or substituted with one or more substituents that do not adversely affect the performance of the second polymeric binder. Preferably, X is a substituted or unsubstituted phenylene group, especially when n is 1.

In Structure (XII), Y is oxy or —NR— wherein R is hydrogen or a substituted or unsubstituted alkyl group having 1 to 10 carbon atoms (such as methyl, ethyl, iso-propyl, n-hexyl, and benzyl groups). Preferably Y is an oxy group.

Also in Structure (XII), Z is a monovalent organic group including but not limited to, a monovalent aliphatic or aromatic group, or a combination thereof. Such groups are defined similar to the multivalent groups described above for X but can also include arylene or alkylene groups, or combinations thereof, with or without carbonyl groups [C(═O)] or amido groups (—NH—) groups, or combinations thereof. For example, useful Z groups include —R′—NHC(═O)R″ groups wherein R′ is a substituted or unsubstituted alkylene group having 2 to 6 carbon atoms (such as ethylene and iso-propylene), and R″ is a substituted or unsubstituted alkyl group having 1 to about 10 carbon atoms (such as methyl, methoxymethyl, ethyl, iso-propyl, n-hexyl, and benzyl groups). One particularly useful Z group is a —CH₂CH₂NHC(═O)-phenyl group.

Z can also be a substituted or unsubstituted alkyl group having 1 to 10 carbon atoms (such as methyl, ethyl, iso-propyl, t-butyl, n-hexyl, and benzyl groups). Particularly useful alkyl groups for Z include those having 1 to 8 carbon atoms (including straight-chain and branched butyl groups).

The second polymeric binder described above generally has an acid number of at least 20 mg KOH/g. To change the acidity of the second polymeric binder, the amount of pending carboxylic acid groups can be adjusted (for example, reduced) by reaction with an oxazoline, or by esterification with an alcohol or alkylhalogenide using known methods.

This second polymeric binder also generally has a number average molecular weight of from about 1,000 to about 250,000 as measured using known techniques.

Moreover, such second polymeric binders can also be represented by the following Structure (XIII):

-(A)ₓ-(B)_{y}- (XIII)

wherein A represents recurring units defined by either Structure (XI) or (XII) or both Structures (XI) and (XII). Thus, multiple types of monomers can be used to provide the A recurring units.

Also in Structure (XIII), x is from about 3 to about 15 mol %, and y is from about 85 to about 97 mol %.

In Structure (XIII), B represents recurring units other than those represented by A. They can be derived from one or more ethylenically unsaturated polymerizable monomers that are capable of copolymerizing with the monomers from which the A recurring units are derived, including maleic acid anhydride. Representative useful monomers for the B recurring units include but are not limited to, (meth)acrylates, (meth)acrylamides, vinyl ethers, vinyl esters, vinyl ketones, olefins, unsaturated imides including N-maleimides, unsaturated anhydrides such as maleic anhydrides, N-vinyl pyrrolidone, N-vinyl carbazole, 4-vinyl pyridine, (meth)acrylonitriles, or styrenic monomers, or any combinations of these monomers. Specific monomers of these and similar classes are described for example, in paragraphs [0044] through [0054] of U.S. Patent Application Publication 2004/0137366.

Preferably, B represents recurring units for Structure (XIII) that are derived from one or more (meth)acrylates, (meth)acrylonitriles, N-phenylmaleimide, or (meth)acrylamides such as N-alkoxyalkylmethacrylamides, or combinations of two or more of such monomers. Some particularly useful monomers from which B recurring units are derived include methyl methacrylate, styrene, ethylenically unsaturated polymerizable monomers having pendant cyclic urea groups, and combinations thereof.

The second polymeric binders comprising Structures XI and XII recurring units can be prepared using a variety of methods. For example, maleimide polymers with pendant carboxylic acid groups can be readily prepared by free radical polymerization of the maleimide monomers corresponding to the recurring units of Structure (XI) using a conventional radical initiator [such as 2,2′-azobis(iso-butyronitrile) or AIBN], or by imidization of the corresponding amine with the anhydride copolymer, in suitable solvents that are inert to the reactants. Polymers comprising Structure (XII) recurring units can be obtained by polymerization of maleic anhydride and the subsequent reaction with an alcohol or secondary amine. Polymers containing Structure (XII) recurring units are available as commercial products such as Scripset® 540 styrene-maleic anhydride copolymers (available from Hercules, Wilmington, Del.). The second polymeric binders can be homopolymers or copolymers.

Thus, useful polymeric binders in the outer layer include copolymers comprising recurring units derived from styrene or a styrene derivative and recurring units derived from maleic anhydride, copolymers comprising recurring units derived from a (meth)acrylate and recurring units derived from a (meth)acrylic acid, or mixtures of both types of copolymers. Further details of these types of copolymers are described in U.S. Patent Application Publication 2007/2007/0065737 (Kitson et al.).

The second polymeric binder is generally present in the outer layer at a dry coverage of from about 1 to about 100 weight %, based on total dry weight of that layer.

The outer layer can also include non-phenolic polymeric materials as film-forming binder materials in addition to or instead of the phenolic resins described above. Such non-phenolic polymeric materials include polymers formed from maleic anhydride and one or more styrenic monomers (that is styrene and styrene derivatives having various substituents on the benzene ring), polymers formed from methyl methacrylate and one or more carboxy-containing monomers, and mixtures thereof. These polymers can comprises recurring units derived from the noted monomers as well as recurring units derived from additional, but optional monomers [such as (meth)acrylates, (meth)acrylonitriles and (meth)acrylamides].

In some embodiments, the outer layer may further include a monomeric or polymeric compound that includes a benzoquinone diazide and/or naphthoquinone diazide moiety. The polymeric compounds can be phenolic resins derivatized with a benzoquinone diazide and/or naphthoquinone diazide moiety as described for example in U.S. Pat. No. 5,705,308 (West et al.) and U.S. Pat. No. 5,705,322 (West et al.). Mixtures of such compounds can also be used. An example of a useful polymeric compound of this type is P-3000, a naphthoquinone diazide of a pyrogallol/acetone resin (available from PCAS, France). Other useful compounds containing diazide moieties are described for example in U.S. Pat. No. 6,294,311 (noted above) and U.S. Pat. No. 5,143,816 (Mizutani et al.).

The monomeric or polymeric compound having a benzoquinone and/or naphthoquinone diazide moiety can be present in the outer layer generally in an amount of from about 5%, based on total dry weight of the outer layer.

The outer layer can optionally include additional compounds that are colorants that may function as solubility-suppressing components for the alkali-soluble polymers. These colorants typically have polar functional groups that are believed to act as acceptor sites for hydrogen bonding with various groups in the polymeric binders. Colorants that are soluble in the alkaline developer are preferred. Useful polar groups include but are not limited to, diazo groups, diazonium groups, keto groups, sulfonic acid ester groups, phosphate ester groups, triarylmethane groups, onium groups (such as sulfonium, iodonium, and phosphonium groups), groups in which a nitrogen atom is incorporated into a heterocyclic ring, and groups that contain a positively charged atom (such as quaternized ammonium group). Further details and representative colorants are described for example in U.S. Pat. No. 6,294,311 (noted above). Particularly useful colorants include triarylmethane dyes such as ethyl violet, crystal violet, malachite green, brilliant green, Victoria blue B, Victoria blue R, and Victoria pure blue BO. These compounds can act as contrast dyes that distinguish the nonimaged areas from the imaged areas in the developed imageable element.

When a colorant is present in the outer layer, its amount can vary widely, but generally it is present in an amount of from about 0.1% to about 30%, based on the total dry weight of the outer layer.

The outer layer can optionally also include printout or contrast dyes, surfactants, dispersing aids, humectants, biocides, viscosity builders, drying agents, defoamers, preservatives, and antioxidants. Coating surfactants are particularly useful.

The outer layer generally has a dry coating coverage of from about 0.2 to about 1 g/m².

Although not preferred, there may be a separate layer that is in between and in contact with the inner and outer layers. This separate layer can act as a barrier to minimize migration of radiation absorbing compound(s) from the inner layer to the outer layer. This separate “barrier” layer generally comprises a third polymeric binder that is soluble in the alkaline developer. If this third polymeric binder is different from the first polymeric binder(s) in the inner layer, it is preferably soluble in from about one organic solvent in which the inner layer first polymeric binders are insoluble. A preferred third polymeric binder is a poly(vinyl alcohol). Generally, this barrier layer should be less than one-fifth as thick as the inner layer, and preferably less than one-tenth as thick as the inner layer.

Preparation of the Imageable Element

The imageable element can be prepared by applying one or more imageable layer formulations over the surface of the aluminum-containing substrate of this invention. Multiple layers can be applied in sequence, for example an inner layer formulation and then an outer layer formulation over the inner layer, using conventional coating or lamination methods. It is important to avoid intermixing of the inner and outer layer formulations.

The various layers can be applied by dispersing or dissolving the desired ingredients in a suitable coating solvent, and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support (such as an on-press printing cylinder).

The selection of solvents used to coat various layers (for example, inner and outer layers) depends upon the nature of the polymeric binders and other components in the formulations. For example, to prevent the inner and outer layer formulations from mixing or the inner layer from dissolving when the outer layer formulation is applied, the outer layer formulation should be coated from a solvent in which the first polymeric binder(s) of the inner layer are insoluble. A skilled artisan would know how to choose solvents to provide the various layers without mixing them.

Alternatively, the formulations may be applied by extrusion coating methods from melt mixtures of the respective layer compositions. Typically, such melt mixtures contain no volatile organic solvents.

Intermediate drying steps may be used between applications of the various layer formulations to remove solvent(s) before coating other formulations. Drying steps may also help in preventing the mixing of the various layers.

After drying the layers, the imageable element (especially multi-layer imageable elements) can be further heat treated at a temperature of from about 40 to about 90° C. for at least 4 hours (preferably at least 20 hours) under conditions that inhibit the removal of moisture from the dried layers. Such heat treatment can be carried out at a temperature of from about 50 to about 70° C. for at least 24 hours. During the heat treatment, the imageable element is wrapped or encased in a water-impermeable sheet material to represent an effective barrier to moisture removal from the precursor, or the heat treatment of the imageable element is carried out in an environment in which relative humidity is controlled to at least 25%. In addition, the water-impermeable sheet material can be sealed around the edges of the imageable element, with the water-impermeable sheet material being a polymeric film or metal foil that is sealed around the edges of the imageable element.

In some embodiments, this heat treatment can be carried out with a stack comprising at least 100 of the same imageable elements (preferably from about 500 elements), or when the imageable element is in the form of a coil.

The imageable elements can have any useful form including, but not limited to, printing plate precursors, printing cylinders, printing sleeves and printing tapes (including flexible printing webs).

Printing plate precursors can be of any useful size and shape (for example, square or rectangular) having the requisite inner and outer layers disposed on a suitable substrate. Printing cylinders and sleeves are known as rotary printing members having the substrate and inner and outer layers in a cylindrical form. Hollow or solid metal cores can be used as substrates for printing sleeves.

Imaging and Development

During use, the imageable element is exposed to a suitable source of radiation, including UV, visible and infrared radiation using a suitable source. It is desired to irradiate using an infrared laser at a wavelength of from about 600 nm to about 1500 nm and typically at a wavelength of from about 700 nm to about 1200 nm. The lasers used to expose the imageable elements are preferably diode lasers, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of from about 800 to about 850 nm or from about 1040 to about 1120 nm.

The imaging apparatus can function solely as a platesetter or it can be incorporated directly into a lithographic printing press. In the latter case, printing may commence immediately after imaging, thereby reducing press set-up time considerably. The imaging apparatus can be configured as a flatbed recorder or as a drum recorder, with the imageable member mounted to the interior or exterior cylindrical surface of the drum. Examples of useful imaging apparatus are available as models of Creo Trendsetter® imagesetters available from Creo Corporation (a subsidiary of Eastman Kodak Company, Burnaby, British Columbia, Canada) that contain laser diodes that emit near infrared radiation at a wavelength of about 830 nm. Other suitable imaging sources include the Crescent 42T Platesetter that operates at a wavelength of 1064 nm and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio). Imaging is generally carried out by direct digital imaging, that is, “computer-to-plate” imaging.

Imaging of the imageable element produces an imaged element that comprises a latent image of imaged (exposed) and non-imaged (non-exposed) regions.

Both high pH and organic solvent-containing developers are useful for processing imageable elements of the present invention. A skilled worker would know how to pick the proper developer for this purpose.

For imaged positive-working imageable elements, development removes the exposed regions of one or more layer, for example, the outer layer and the underlying layers (including the inner layer), and exposes the hydrophilic surface of the substrate of this invention. The exposed (or imaged) regions of the hydrophilic surface of the substrate repel ink while the non-exposed (or non-imaged) regions of the outer layer accept ink. The imaged elements are generally developed using conventional processing conditions.

Following development, the imaged element can be rinsed with water and dried in a suitable fashion. The dried element can also be treated with a conventional gumming solution (preferably gum arabic).

The imaged and developed element can also be baked in a postbake operation that can be carried out to increase run length of the resulting imaged element. Baking can be carried out, for example at a temperature of from about 220° C. to about 240° C. for a time of from about 7 to about 10 minutes, or at about 120° C. for 30 minutes.

A lithographic ink and fountain solution can be applied to the printing surface of the imaged element for printing. Ink is taken up by the oleophilic regions of the outer layer and the fountain solution is taken up by the hydrophilic surface (usually the aluminum-containing substrate of this invention) revealed by the imaging and development process. The ink is then transferred to a suitable receiving material (such as cloth, paper, metal, glass, or plastic) to provide a desired impression of the image thereon. An intermediate “blanket” roller is often used to transfer the ink from the imaged member to the receiving material.

The following examples are provided to illustrate the practice of the invention but are by no means intended to limit the invention in any manner.

### EXAMPLES

The components and materials used in the examples and analytical methods were as follows:

Binder A represents a copolymer of N-phenylmaleimide, methacrylamide, and methacrylic acid (40.2:34.9:24.9 mol %).

BLO represents γ-butyrolactone.

DEK represents diethyl ketone.

Ethyl violet is C.I. 42600 (CAS 2390-59-2, λₘₐₓ=596 nm) having a formula of p-(CH₃CH₂)₂NC₆H₄)₃C⁺Cl⁻ (Aldrich Chemical Company, Milwaukee, Wis., USA).

IR Dye A was obtained from Eastman Kodak Company and has the following structure:

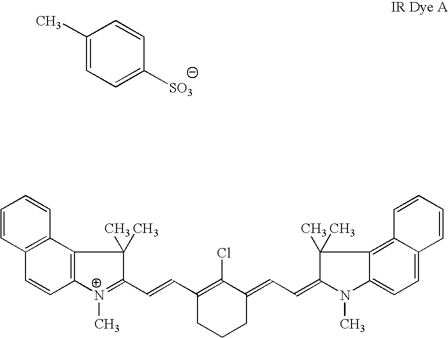

IR Dye B that was obtained from FEW Chemicals GmbH and has the following structure:

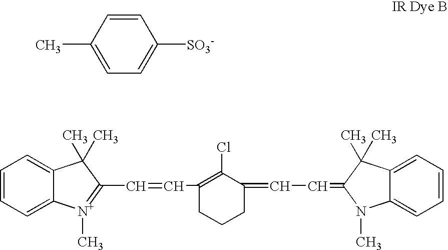

D11 is a colorant that was obtained from PCAS (Longjumeau, France) and has the following structure:

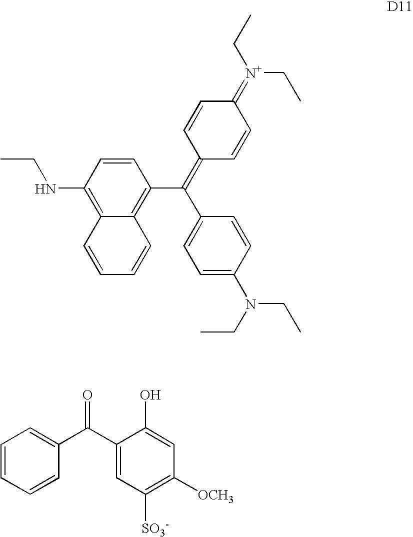

P3000 is a 215 naphthoquinonediazide sulfonate ester of pyrogallol acetone condensate that was obtained from PCAS (Longjumeau, France).

PD140A is a novolak resin (75% m-cresol and 25% p-cresol, MW 7000) that was obtained from Borden Chemical (Louisville, Ky.).

PGME represents 1-methoxypropan-2-ol (also known as Dowanol PM).

Synthesis of poly(vinyl Phosphonic Acid) (Polymer 1):

Ethyl acetate (3650 g) was charged into a 10-liter reaction vessel equipped with a condenser and heated at 70° C. Vinyl phosphonic acid (1950 g) monomer was mixed into 1000 g of ethyl acetate. AIBN (52 g) was dissolved in this monomer mixture and the monomer mixture was added dropwise into the reaction vessel at 70° C. over 4 hours. After this addition, the reaction mixture was kept at 70° C. for 2 hours and then cooled down to room temperature. Precipitated white powder was isolated by filtration and washed with 1 liter of ethyl acetate to provide the desired Polymer 1.

### Synthesis of Co-Polymer of Vinyl Phosphonic Acid and Methacrylic Acid (Polymer 2):

Ethyl acetate (3650 g) was charged into a 10-liter reaction vessel equipped with a condenser and heated at 70° C. Vinyl phosphonic acid monomer (390 g) and methacrylic acid (1243 g) were mixed into ethyl acetate (1000 g). AIBN (52 g) was dissolved into this monomer mixture and the monomer mixture was added dropwise into the reaction vessel at 70° C. over 4 hours. After this addition, the reaction mixture was kept at 70° C. for 2 hours and then cooled down to room temperature. The precipitated white powder was isolated by filtration and washed with 1 liter of ethyl acetate to provide the desired Polymer 2.

### Synthesis of Acrylic Resin 1:

Into a 10 liter flask equipped with a stirrer, a condenser, and a dropping funnel were added 2990 g of N,N-dimethylacetamide which was then heated at 90° C. Under a nitrogen atmosphere, a mixture of 740.5 g of N-phenylmaleimide, 1001 g of methacrylamide, 368 g of methacrylic acid, 643 g of acrylonitrile, 203.6 g of Phosmer M (Unichemical), 222.5 g of styrene, 10.6 g of AIBN, 16 g of n-dodecylmercaptan, and 2670 g of N,N-dimethylacetamide was dropped into the flask over 2 hours. To the mixture were added 5.3 g of AIBN and heated at 100° C. and stirred for 4 hours. During the reaction, 5.3 g of AIBN were added at 1-hour intervals. After the reaction, the mixture was cooled down to 60° C. and poured into 50 liters of water. The resulting solid was filtered, washed, and dried at 60° C. for 24 hours under vacuum to provide 2873 g of the desired Acrylic Resin 1 (yield 90%).

Aqueous post-treatment solutions were prepared with various amounts of interlayer polymers and aluminum ion concentrations as shown in TABLE I below.

TABLE I

| Post- | | | |
|---|---|---|---|
| Treatment | | Polymer concentration | Al⁺³ concentration |
| Solution | Polymer | (g/l) | (g/l)* |
| 1 | 1 | 0.5 | 0.005 |
| 2 | 1 | 0.5 | 0.020 |
| 3 | 1 | 1.0 | 0.010 |
| 4 | 1 | 1.0 | 0.040 |
| 5 | 2 | 0.5 | 0.005 |
| 6 | 2 | 0.5 | 0.020 |
| 7 | 2 | 1.0 | 0.010 |
| 8 | 2 | 1.0 | 0.040 |
| 9 | 1 | 0.5 | 0.000 |
| 10 | 1 | 1.0 | 0.000 |
| 11 | 2 | 0.5 | 0.000 |
| 12 | 2 | 1.0 | 0.000 |

*Al⁺³ was added as Al₂(SO₄)₃•16H₂O. The concentrations of Al⁺³ were calculated as Al⁺³ (g/l) = 2 × M(Al⁺³)/M_{(Al}_{₂}_{(SO}_{₄}₎_{₃}_{16H}_{₂}_{O)}.

### INVENTION & COMPARATIVE EXAMPLES

Aluminum-containing substrates were prepared from a 0.50 μm Ra aluminum sheet that was degreased using sodium hydroxide and electrolytically grained in 20% hydrochloride. It was then anodized at 2 A/dm² using 20% sulfuric acid, washed, and dried. An oxide layer of 2.7 g/m² was obtained. The resulting substrates were dipped into the individual aqueous post-treatment solutions shown in TABLE I at 60° C. for 10 seconds. Twelve different treated substrates used in Examples 1-8 and Comparative Examples 1-4 were obtained in this manner using the aqueous post-treatment solutions shown in TABLE II below.

TABLE II

| Substrate | Aqueous Post-Treatment Solution |
|---|---|
| Example 1 | 1 |
| Example 2 | 2 |
| Example 3 | 3 |
| Example 4 | 4 |
| Example 5 | 5 |
| Example 6 | 6 |
| Example 7 | 7 |
| Example 8 | 8 |
| Comparative Example 1 | 9 |
| Comparative Example 2 | 10 |
| Comparative Example 3 | 11 |
| Comparative Example 4 | 12 |

A 1 liter solution of Polymer 2 (0.5 g/l) and aluminum (+3) ion (0.02 g/l) was prepared and heated to 60° C. to make an interlayer solution (Solution A) having a pH of 2.80 and conductivity of 0.58 mS/cm.

Replenisher A solution of Polymer 2 was prepared having 20 g/l of Polymer 2 (Replenisher A). A Replenisher B solution of Al³⁺ was prepared at 45.15 g/l of Al⁺³.

Aluminum plate was treated continuously before applying the interlayer as described above. The plate was moved at 30 m/minute. The aluminum substrate was dipped into Solution A continuously while Solution A was replenished with Replenisher A at 0.3 liter/min, Replenisher B at 0.02 liter/min, and deionized water at 13 liter/min. The amount of deionized water was adjusted while maintaining Solution A at a pH between 2.7 and 2.9 and conductivity between 0.50 and 0.70 mS/cm.

The aluminum substrates were tested at 0 min (start of treatment, Example 9), 1 hour after treatment was begun (Example 10), and 3 hours after treatment was begun (Example 11). The results of the three Invention Examples are shown in the following TABLE III.

TABLE III

| | pH | Conductivity (mS/cm) | Substrate |
|---|---|---|---|
| Start (0 min) | 2.80 | 570 | Example 9 |
| 1 hour after | 2.82 | 550 | Example 10 |
| 3 hours after | 2.81 | 555 | Example 11 |

An inner layer coating formulation was prepared using the components shown in TABLE IV below.

TABLE IV

| Component | Amount (g) |
|---|---|
| Methyl ethyl ketone | 47.28 |
| Propylene glycol 1-monomethyl ether | 28.37 |
| γ-Butyrolactone | 9.46 |
| Water | 9.46 |
| Acrylic Resin 1 | 3.95 |
| IR Dye A | 0.50 |
| IR Dye B | 0.40 |
| D11 | 0.10 |
| Paintad 19 | 0.05 |

An upper layer coating formulation was prepared using the components shown in the following TABLE V.

TABLE V

| Component | Amount (g) |
|---|---|
| Methyl isobutyl ketone | 66.32 |
| Acetone | 19.00 |
| Propylene glycol 1-monomethyl ether 2-acetate | 9.50 |
| SMA resin (average MW 2,000)* | 4.93 |
| BOH-M | 0.02 |
| Paintad 19 | 0.05 |

*SMA resin is a co-polymer of styrene and maleic anhydride (molar ratio of 1:1).

Positively-working imageable elements were prepared by coating the lower layer coating formulation, using a roll-coater, onto an aluminum-containing substrate and dried for 2 minutes at 100° C. The upper layer coating formulation was then coated onto the dried lower layer and dried for 2 minutes at 100° C. The coating weights of the lower and upper layers were 1.5 g/m² and 0.5 g/m², respectively.

An alkaline developer was prepared by mixing the components listed in TABLE VI below.

TABLE VI

| Component | Amount (g) |
|---|---|
| Deionized water | 700 |
| Monoethanolamine | 10 |
| Diethanolamine | 30 |
| Pelex NBL (KAO Corporation) | 200 |
| Benzyl alcohol | 60 |

The pH and conductivity of the developer were 11.5 and 1.2 mS/cm, respectively.

The prepared imageable elements were exposed using a PTR4300 image setter (Dainippon Screen) at 150 mJ/cm². They were developed in the noted developer that had been diluted 5 times in a commercial processor P-1310X (Kodak Polychrome Graphics), at 30° C. for 15 seconds and then treated with the finishing gum PF2 (Kodak Polychrome Graphics at 1+1.5 dilution) to provide lithographic printing plates.

A printing test was carried out using the following methods and printing conditions:

Printing machine: R-201 (Man Roland),

Ink: Space color, Fusion G Magenta (Dai Nippon Ink and Chemical),

Fountain solution: NA108W (Dai Nippon Ink and Chemical) and 1% and isopropyl alcohol at 1%.

### Limited Water Level Test:

All tested printing plates were used to print at a 60 water level (Maximum: 100) using the noted mentioned printing condition. The shadow areas of printed sheets were plugged using the lower water level. The level of the water causing the shadow areas to be plugged was evaluated. The desired results were to obtain good prints with the use of less water and little plugging.

### Ink Clean-Up Property Test:

Five thousand sheets of paper were printed using printing conditions noted above. Then printing was stopped and ink was put on the whole printing plate using an ink roller without a fountain solution. After 30 minutes, printing was re-started and fountain solution was supplied and ink removed from the non-imaged areas. The ink clean-up property (or “ink roll up test”) was evaluated by determining the number of the sheets that were required to show no ink in the non-imaged and shadow areas.

The results of these tests are shown in the following TABLE VII.

TABLE VII

| | Limited Water | Ink clean-up | |
|---|---|---|---|
| | Level | property test | |
| | Test | (Number of sheets) | Comment |
| Example 1 | 40 | 40 | |
| Example 2 | 35 | 35 | |
| Example 3 | 40 | 40 | |
| Example 4 | 35 | 35 | |
| Example 5 | 35 | 30 | |
| Example 6 | 30 | 25 | |
| Example 7 | 35 | 30 | |
| Example 8 | 30 | 25 | |
| Example 9 | 30 | 25 | |
| Example 10 | 30 | 25 | |
| Example 11 | 30 | 25 | |
| Comparative | 50 | >100 | Shadow areas were |
| example 1 | | | plugged after only |
| | | | 100 sheets |
| Comparative | 55 | >100 | Shadow areas were |
| example 2 | | | plugged after only |
| | | | 100 sheets |
| Comparative | 50 | 90 | |
| example 3 | | | |
| Comparative | 55 | 90 | |
| example 4 | | | |

Printing plates obtained from Examples 1-11 that comprised an aluminum-containing substrate that had been treated according to the present invention showed improved printing properties compared to the printing plates obtained from the Comparative Examples 1-4 when the water was limitation and ink clean-up property tests. This demonstrates that controlling the polymer and Al⁺³ concentrations during treatment of the aluminum-containing substrate within chosen target concentrations provided improved printability and ink clean-up properties since the highly hydrophilic substrate repelled ink to a great degree.

The invention has been described in detail with particular reference to certain preferred embodiments thereof, but it will be understood that variations and modifications can be effected within the spirit and scope of the invention.

1. A method of preparing an aluminum-containing substrate, said method comprising:
treating an aluminum support surface having an anodic oxide layer, with an aqueous post-treatment solution comprising a polymer derived from vinyl phosphonic acid and an Al⁺³ salt, wherein the concentration of said polymer is maintained in said post-treatment solution at a concentration of within ±50% of a target polymer concentration of from about 1.5×10⁻⁴ to about 1.5 mol phosphonic acid groups per liter, and the concentration of Al⁺³ is maintained in said post-treatment solution at a concentration of within ±50% of target Al⁺³ concentration within the range of from about 1×10⁻⁶ to about 1×10⁻¹ mol/liter,
said treating step being sufficient to deposit at least 3×10⁻⁶ mole of phosphonic acid groups per m² of said support.

2. The method of claim 1 wherein, during said treating step, the concentration of said polymer is maintained in said post-treatment solution at a concentration of within ±15% of target polymer concentration within the range of from about 1×10⁻³ to about 1×10⁻¹ mol phosphonic acid groups per liter.

3. The method of claim 1 wherein, during said treating step, the concentration of Al⁺³ is maintained in said post-treatment solution at a concentration of within ±15% of target Al⁺³ concentration within the range of from about 1×10⁻⁵ to about 1×10⁻³ mol/liter.

4. The method of claim 1 wherein said polymer is a homopolymer derived from vinyl phosphonic acid or a copolymer derived from vinyl phosphonic acid and (meth)acrylic acid.

5. The method of claim 1 wherein the molar ratio of phosphonic acid group to Al⁺³ ion in said post-treatment solution is from about 1000:1 to about 1:10, and said post-treatment solution has a pH of from about 1.5 to about 7.

6. The method of claim 1 wherein the target concentration of said polymer is maintained in said post-treatment solution by replenishing said post-treatment solution with one or more replenisher solutions, each at a given rate, to maintain, increase or decrease the polymer concentration, Al⁺³ concentration, or both concentrations.

7. The method of claim 1 wherein the concentrations of polymer and Al⁺³ are maintained by replenishing said post-treatment solution with separate replenisher solutions containing polymer and Al⁺³, respectively.

8. The method of claim 1 wherein said target aluminum and polymer concentrations [Al⁺³]₁ and [polymer]₁, respectively, are measured during said treating step and maintained by adding one or more of the following replenishment solutions to said post-treatment solution at pre-determined rates:
a) a solution having [polymer]₁ but also having an aluminum ion concentration of 0 or substantially lower than said [Al⁻³]₁ to reduce the post-treatment solution aluminum ion concentration to said [Al⁺³]₁,
b) a solution having [polymer]₁ but also having an aluminum ion concentration substantially higher than said [Al⁻³]₁ to increase the post-treatment solution aluminum ion concentration to said [Al⁺³]₁,
c) a solution having said [Al⁺³]₁ but also having a polymer concentration substantially higher than said [polymer]₁ to increase the post-treatment solution polymer concentration to said [polymer]₁.

9. The method of claim 1 wherein said support has been previously anodized with sulfuric acid.

10. The method of claim 1 wherein said treating step is carried out at a temperature of from about 20 to about 80° C. for from about 1 to about 60 seconds.

11. The method of claim 1 wherein said support has an anodic oxide layer at a coverage of at least 0.3 g/m².

12. The aluminum-containing substrate prepared according claim 1.

13. An imageable element comprising a substrate prepared according to claim 1 and having one or more imageable layers disposed on said substrate.

14. The element of claim 13 wherein said imageable layer is sensitive to thermal energy.

15. The element of claim 13 wherein said imageable layer is sensitive to infrared radiation.

16. The element of claim 13 wherein said imageable layer is a positive-working imageable layer.

17. The element of claim 13 that is a positive-working imageable element comprising a single imageable layer disposed on said substrate.

18. The element of claim 13 that is a positive-working imageable element comprising inner and outer imageable layers disposed on said substrate.

19. The element of claim 18 wherein said outer layer comprises a polymeric binder that is:
a copolymer comprising recurring units derived from styrene or a styrene derivative and recurring units derived from maleic anhydride,
a copolymer comprising recurring units derived from a (meth)acrylate and recurring units derived from a (meth)acrylic acid, or
mixtures of both types of copolymers.

20. The element of claim 13 that is a lithographic printing plate precursor wherein said imageable layer is ink receptive and not alkaline developer soluble or dispersible before imaging.
